(19) United States
(12) Patent Application Publication
(10) Pub. No.: US 2010/0290174 A1
(43) Pub. Date: Nov. 18, 2010

(54) POWER COMPONENT MAGAZINE, POWER COMPONENTS, A POWER COMPONENT ASSEMBLY AND METHODS OF ASSEMBLY

(76) Inventor: Michael John Harrison, Christchurch (NZ)

Correspondence Address: MYERS BIGEL SIBLEY & SAJOVEC, PO BOX 37428, RALEIGH, NC, 27627, US

(21) Appl. No.: 12/305,782

(22) PCT Filed: May 17, 2007
(86) PCT No.: PCT/NZ07/00116

§ 371 Date: Jul. 29, 2010

(30) Foreign Application Priority Data
Jun. 28, 2006 (NZ) 548211

(51) Int. Cl. H02B 1/26; H05K 13/00

(52) U.S. Cl. 361/601; 29/825

(57) ABSTRACT

A power component magazine and power components for the magazine utilise a common foam factor enabling one magazine to accommodate a range of power components of different capacity. A wiring system is employed that simplifies wiring of the magazine during assembly. The magazine construction provides protection against incorrect power components being inserted in a magazine.

### FIELD OF THE INVENTION

This invention relates to a power component magazine, power components for the magazine, a magazine and power component assembly and to methods of assembly. More particularly, although not exclusively, the invention relates to a modular rectifier system allowing a required rectifier assembly to be easily constructed from a small range of standard modular components.

### BACKGROUND OF THE INVENTION

In many power applications there is a need to provide assemblies of power components to provide the required capacity. Typically one or more magazine containing a number of power components, such as rectifier modules, is provided. Typically a range of power components of different power handling capacity are provided having different form factors. This means that a magazine must be made that is specific to the power modules employed. Further, the connectors for each module are typically specifically wired to supply lines for a specific application.

This requires a large inventory of components to be maintained and makes assembly time consuming and expensive.

It would be desirable to provide a small range of modular components from which all required assemblies may be constructed and which enables wiring for a specific application to be easily realised. It would also be desirable to provide protection against power components being inserted in the incorrect magazine.

It is an object of the invention to provide a solution satisfying these demands or to at least provide the public with a useful choice.

### SUMMARY OF THE INVENTION

According to a first aspect there is provided a power component magazine having a plurality of bays for receiving a plurality of components and a connector for each bay for providing electrical connection between a component and power lines associated with the magazine, wherein the connectors are movable relative to the magazine so as to connect with a component to provide a three-phase interface in a first position and a single phase interface in a second position.

The connectors may be moved up and down between the first and second positions. This may be achieved by securing the connectors to the rear panel of the power component magazine that is movable up and down.

According to a further aspect there is provided a power component magazine having a plurality of bays for receiving a plurality of components and a connector for each bay for providing electrical connection between a component and power lines associated with the magazine, wherein each connector includes a first AC terminal and every third first AC terminal is connected to a respective power line.

Each connector may include a second AC terminal and every third connector of each second AC terminal may be connected to a respective power line. Each connector may also include an earth terminal connected to a common earth line.

According to a further aspect there is provided a method of assembling a power component magazine comprising:

a. supplying a power component magazine as above; and
b. connecting all power lines to a common single phase AC supply line.

There is further provided a method of assembling a power component magazine comprising:

a. supplying a power component magazine as above; and
b. connecting the power lines to three respective three phase AC supply lines.

There is further provided a method of assembling a power component magazine comprising:

a. supplying a power component magazine as above; and
b. connecting two of the power lines to two respective AC supply lines.

There is further provided a method of assembling a power component magazine comprising:

a. supplying a power component magazine as above;
b. connecting all power lines connected to first terminals to a first single phase AC supply line and connecting all power lines connected to second terminals to a second single phase AC supply line.

There is further provided a method of assembling a power component magazine comprising:

a. supplying a power component magazine as above;
b. connecting all power lines connected to first terminals to a first single phase AC supply line and connecting all power lines connected to second terminals to a second neutral supply line.

There is further provided a method of assembling a power component magazine comprising:

a. supplying a power component magazine as above; and
b. connecting the power lines to three respective three phase AC supply lines.

The power lines connected to each first AC terminal of each connector are preferably connected to a different three phase AC power supply line than the second AC terminal of each connector.

There is further provided a method of assembling a power component magazine comprising:

a. supplying a power component magazine as above; and
b. connecting the power lines of the first terminals of each connector to three respective three phase AC supply lines; and
c. connecting the power lines of the second terminals of each connector to a neutral supply line.

There is further provided a power component assembly comprising:

a. a power component magazine having a plurality of bays, each of a constant form factor; and
b. a plurality of power component modules, at least one of different dimensions, adapted to be accommodated within the bays, wherein the dimensions of all power component modules are multiples of the bay form factor.

The multiples are preferably integer multiples of 1.75 inches in component width and the magazine preferably has 10 bays.

There is further provided a family of power components having different power ratings and different form factors wherein the form factor of each power component fits within a multiple of a standard form factor and each power component has connectors allowing engagement to a standard complementary connector. The family of power components preferably includes single phase and three phase power components in which the terminals of each single phase power component have a first relationship with each single phase power component and the terminals of each three phase power component have a second relationship with each three phase power component, different to the first relationship.

There is further provided a method of assembling a power supply comprising a component magazine having a rear connector plate securable in a first or second position and a plurality of power components, the method comprising the steps of:

a. Securing the connector plate in the first or second position in dependence upon whether the power supply is to be a single or three phase power supply; and
b. Inserting the power components in bays of the component magazine.

### BRIEF DESCRIPTION OF THE DRAWINGS

The accompanying drawings which are incorporated in and constitute part of the specification, illustrate embodiments of the invention and, together with the general description of the invention given above, and the detailed description of embodiments given below, serve to explain the principles of the invention.

FIG. 1 shows schematic front view of a power component magazine according to one embodiment;

FIG. 2 shows the magazine of FIG. 1 with small power components inserted;

FIG. 3 shows the magazine of FIG. 1 with large power components inserted;

FIG. 4 shows a top, rear side perspective view of one realization of a power component magazine;

FIG. 5 shows a perspective view of a connector of the power component magazine shown in FIG. 4;

FIG. 6 shows a rear perspective view of a power component magazine showing the PCB edge connector interface; and

FIGS. 7 to 15 show possible wiring configurations for the power component magazine shown in FIGS. 4 and 5.

### DESCRIPTION OF EMBODIMENTS OF THE INVENTION

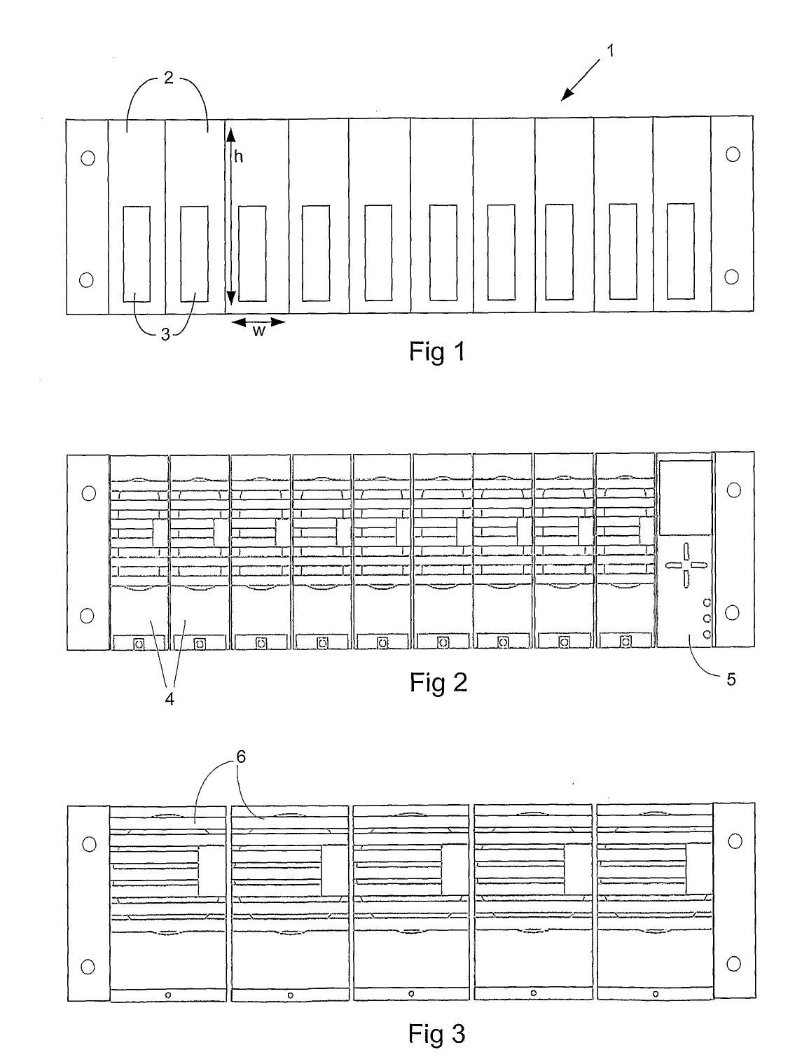

FIG. 1 shows a schematic view of a power component magazine according to one embodiment. Magazine 1 has a plurality of bays 2 having connectors 3 at the rear of each bay. There are no dividers between bays so has a component may occupy multiple bays. Each bay 2 has a constant form factor of height h and width w. The width w of each bay is preferably 1.75 inches and the height of each bay is preferably 5.25 inches.

Power components for the magazine are designed to be multiples of the form factor of each bay. FIG. 2 shows a number of power components in the form of lower power rectifier modules 4 each occupying a single bay and a monitoring module 5 also occupying a single bay. In this case each rectifier module 4 is connected to an associated connector 3 of each bay. FIG. 3 shows a number of a high power rectifier modules 6 each occupying two bays. In this case each rectifier model 6 is connected to both connectors of the two bays it occupies.

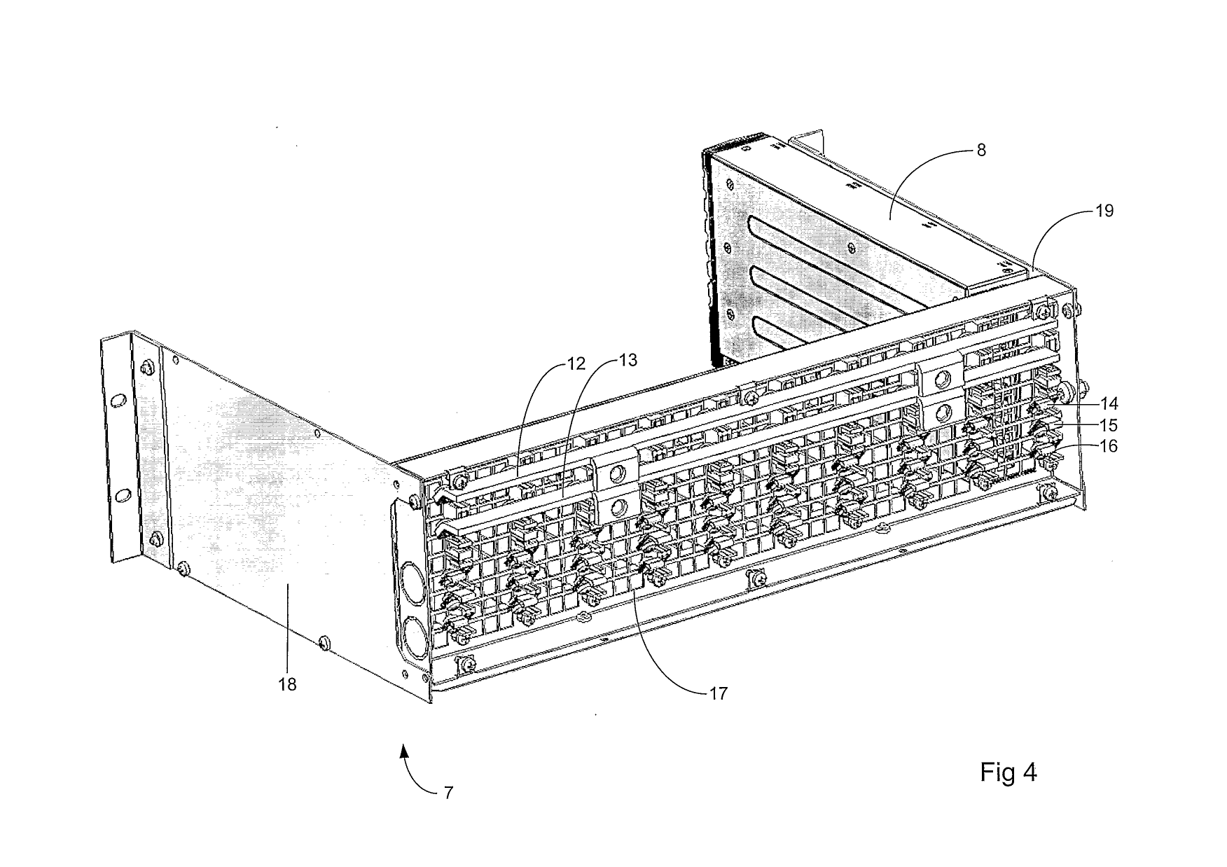

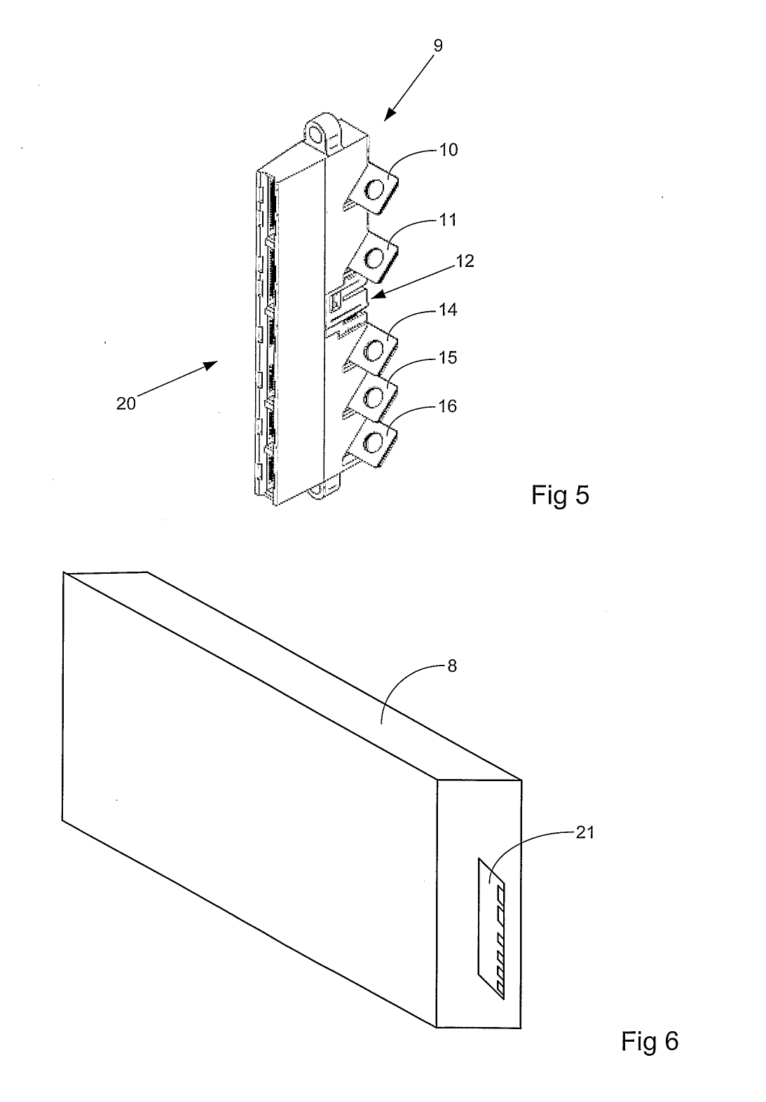

FIG. 4 shows a perspective view of a power component magazine 7 having a power component 8 occupying a single bay. Connectors of the form of connector 9 shown in FIG. 5 are provided at the rear of each bay. Each connector 9 has DC terminals 10 and 11 which connect to the DC bus bars 12 and 13. Each connector 9 also has an earth terminal 14 and AC terminals 15 and 16.

Magazine 7 consists of a rear panel 17 secured to side walls 18 and 19 at each end. Connectors of the form shown in FIG. 5 are secured to rear panel 17 at the rear of each bay. Each power component 8 includes a PCB edge connector 21 that engages with corresponding contacts provided at the front face 20 of connector 9. Each PCB edge connector 21 is preferably double sided and engages with opposing pairs of contacts of each connector 9. This reduces the load carried by each connection and provides redundancy in case of failure. Terminals 22 provide a serial connection between power components and a monitoring or control module so that the status and performance of a power component may be monitored and controlled.

According to a preferred embodiment the PCB edge connector 21 for single phase embodiments is higher or lower with respect to the position of the PCB edge connector for three phase embodiments. This is to prevent three phase power components being inserted into a magazine configured for single phase operation or vice versa. According to a preferred embodiment the magazine may be configured at construction to selectively place connectors 9 in a raised or lowered configuration. The side walls 18 and 19 and the back panel 17 of the magazine preferably have apertures enabling fasteners to secure the back panel to side walls 18 and 19 in a raised or lowered configuration. Thus, a magazine may be constructed specifically for three phase or single phase operation simply by selecting the fastening apertures so as to position rear panel 17 in a raised or lowered position with respect to side walls 18 and 19.

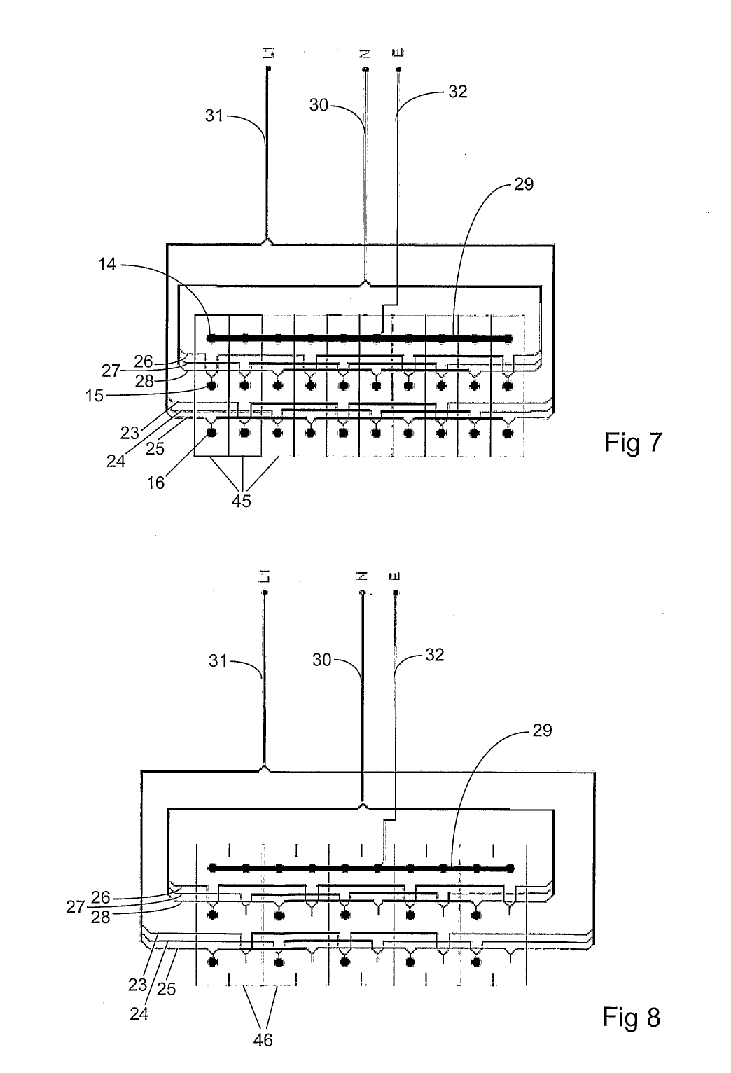

Referring now to FIGS. 7 to 15 possible wiring configurations for the AC terminals of each connector (i.e. terminals at 14, 15 and 16 of FIG. 5) will be described. FIGS. 7 and 8 disclose single phase wiring configurations suitable for small and a large single phase power components. In all the embodiments described below a common wiring system is used. Every third lower AC terminal (terminal 16 in FIG. 5) is connected to a respective power line 23, 24 or 25 as shown. Likewise every third middle AC terminal (10 or 15 in FIG. 5) is connected to a respective power line 26, 27 or 28. All upper AC terminals (14 in FIG. 5) are interconnected by earth line 29. These connections may be made when the magazine is assembled or prior to shipment of the component parts.

FIG. 7 shows a wiring configuration suitable for low-power single phase power components 46. In this configuration power lines 26, 27 and 28 are all connected to neutral line 30 whilst power lines 23, 24 and 25 are connected to AC phase supply line 31. Thus, if power lines 23 to 29 are pre-connected then a person assembling the magazine simply needs to connect power lines 26 to 28 to neutral line 30, power lines 23 to 25 to AC supply line 31 and earth line 29 to earth supply line 32.

FIG. 8 shows an identical wiring configuration. However, in this case high-power power components 46 have been installed and so only every alternate connector connects to the AC supply lines (as indicated by the light coloured dots). It will be appreciated that if a neutral connection is not required that the connections to the middle AC terminals (i.e. via power lines 26 to 28) are not required.

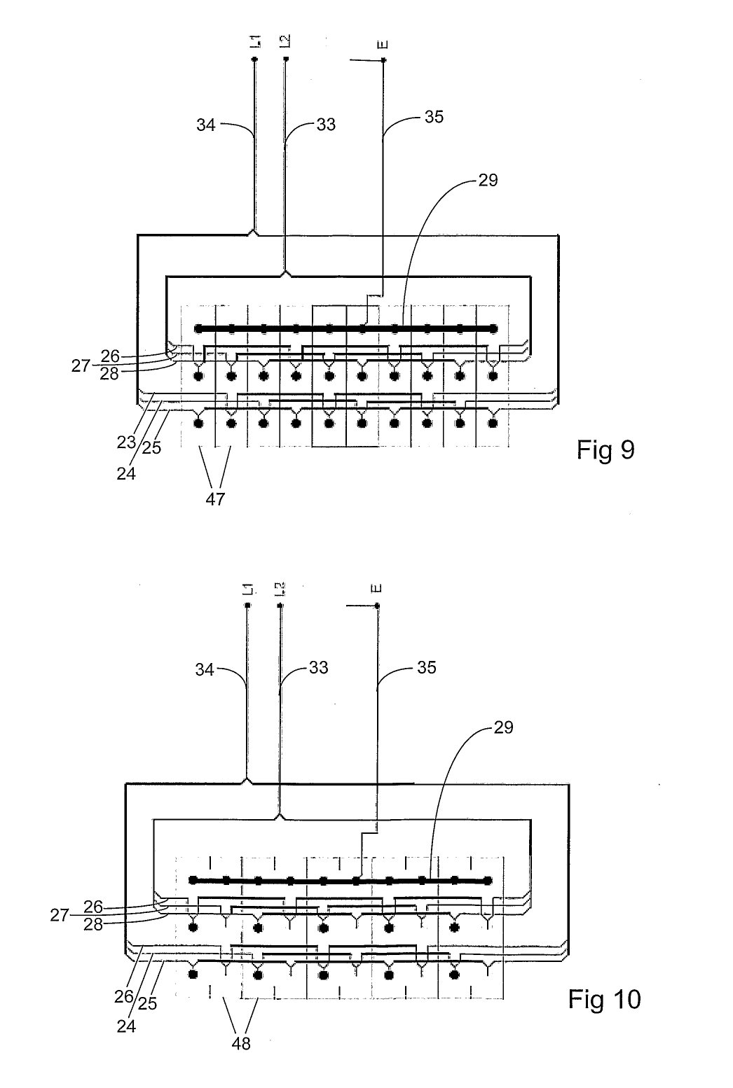

FIG. 9 shows a two phase embodiment in which AC power lines 26 to 28 are connected to a first AC supply line 33 and AC power lines 23 to 25 are connected to a second AC supply line 34. Earth line 29 is connected to earth supply line 35 (which is also connected to a neutral supply line). This arrangement allows to AC phases to be supplied to each low-power power component 47. FIG. 10 shows a similar wiring configuration for high-power power components 48 (i.e. the light coloured dots illustrate AC terminals which formed a connection to the power components).

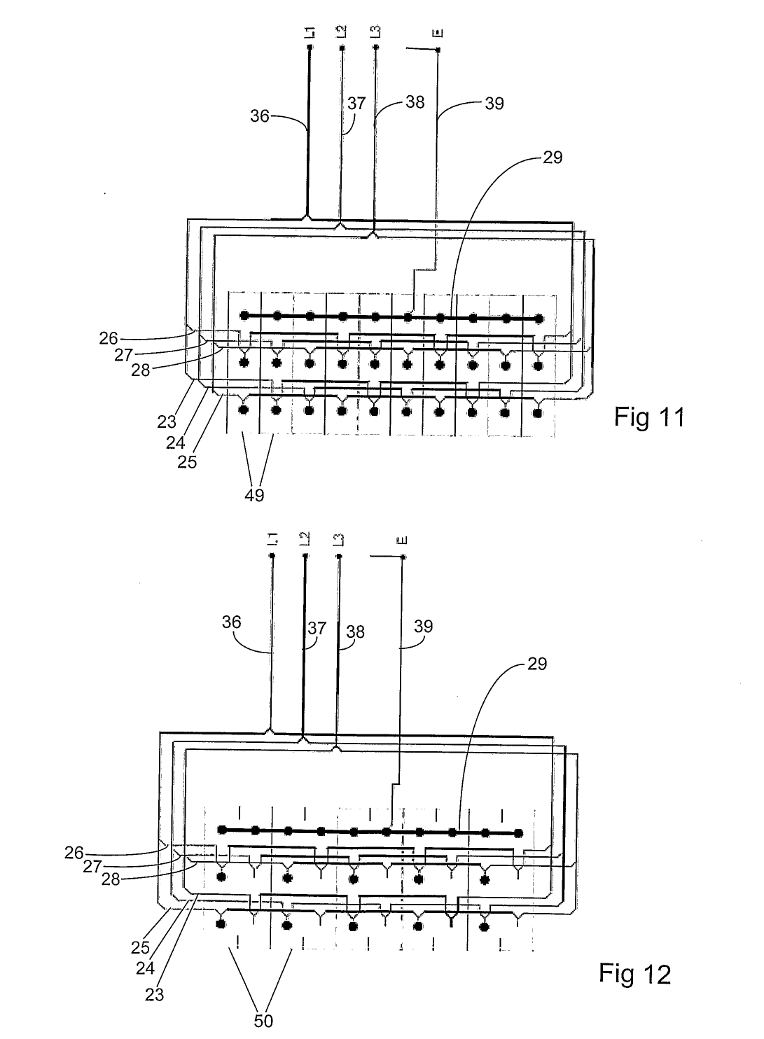

FIG. 11 shows a wiring configuration for a three-phase supply to single phase low-power power components 49. In this case each power line 26 to 28 is connected to a respective three-phase AC supply line 36 to 38. Likewise each power line 23 to 25 is connected to a respective three-phase AC supply line 36 to 38. Earth power line 29 is connected to earth supply line 39. It should be noted that the AC terminals of each connector are connected to different AC supply lines 36 to 38. FIG. 12 shows the same wiring configuration but with high-power single phase AC power components 50 installed (the light coloured dots illustrating AC terminals which are not connected to the power components).

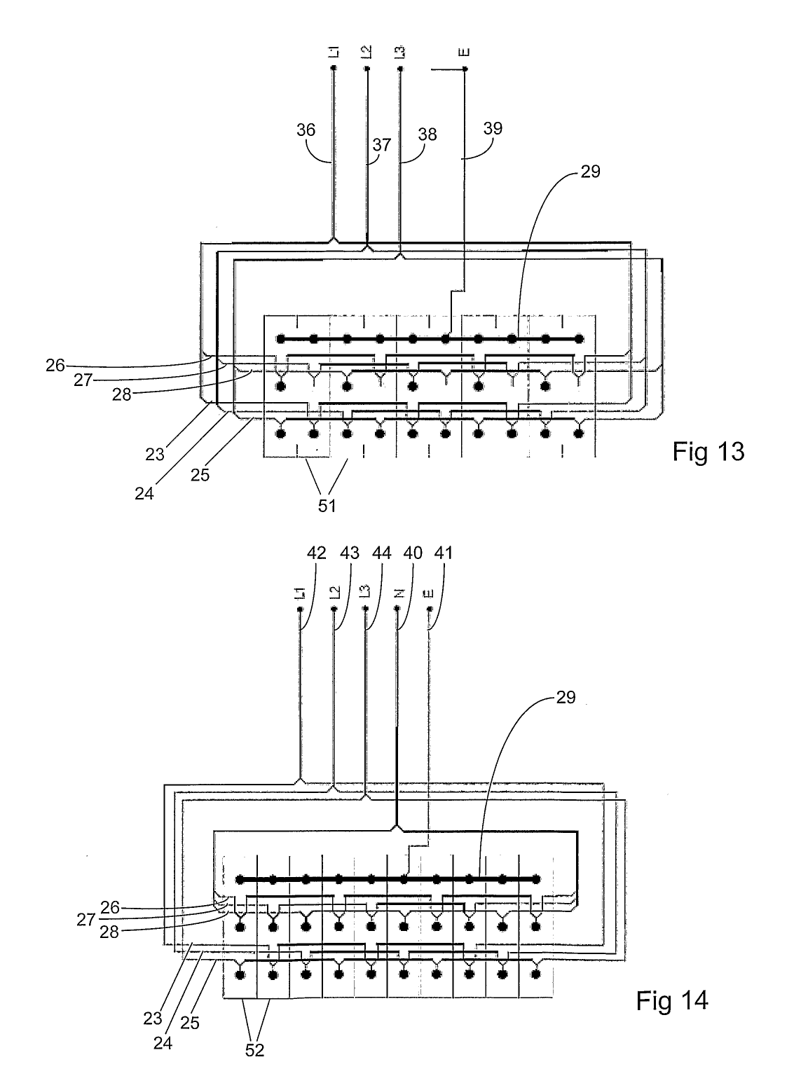

FIG. 13 shows a wiring configuration for three-phase power components 51. The wiring configuration is the same as that shown in FIGS. 11 and 12. However, it will be seen that in this implementation that the three phases are supplied to each power component via two connectors. Thus, a common wiring arrangement can be employed for all three-phase power supplies.

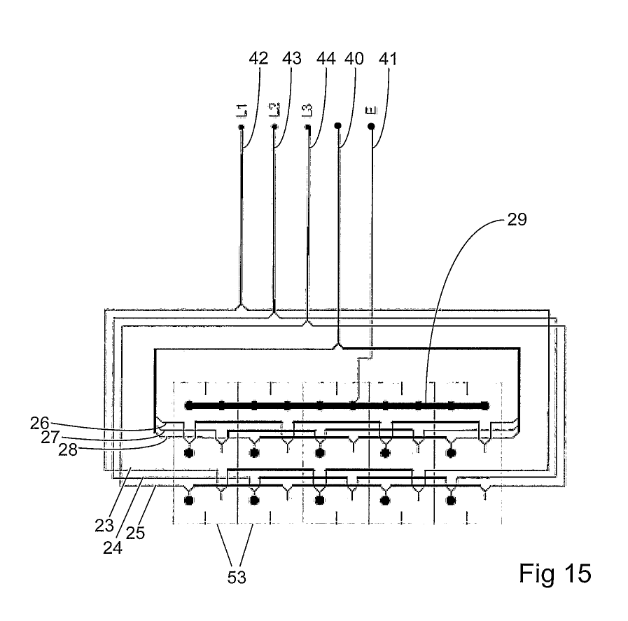

FIG. 14 shows a wiring arrangement for single phase low-power power components 52 from a three-phase supply where neutral and earth connections are required. In this case power lines 26 to 28 at connected to neutral supply line 40, earth line 29 annexed to earth supply line 41 and three-phase supply lines 42 to 44 connect to power lines 23 to 25 respectively. In this arrangement each power component receives phase, neutral and earth suppliers. The wiring arrangement is the same in FIG. 15 except that high power single phase power components 53 have been inserted in the magazine (light coloured dots indicating AC terminals not connected to power components).

There is thus provided a power component magazine that can be used for single phase at low-power, single phase high-power and three-phase power components. The modular family of power components, being multiples of a standard form factor, allows a standard magazine to be employed. A common wiring system that may be employed so that simple connections to supply lines can configure the magazine for single phase, two phase or three-phase applications. Providing two configurations for the back panel of the power component magazine enables the connectors to be raised or lowered, providing protection against single phase power components being inserted into a three-phase magazine or vice versa.

While the present invention has been illustrated by the description of the embodiments thereof, and while the embodiments have been described in detail, it is not the intention to restrict or in any way limit the scope of the appended claims to such detail. Additional advantages and modifications will readily appear to those skilled in the art. Therefore, the invention in its broader aspects is not limited to the specific details, representative apparatus and method, and illustrative examples shown and described. Accordingly, departures may be made from such details without departure from the spirit or scope of the Applicant's general inventive concept.

1. A power component magazine having a plurality of bays for receiving a plurality of components and a connector for each bay for providing electrical connection between a component and power lines associated with the magazine, wherein the connectors are movable relative to the magazine so as to connect with a component to provide a three-phase interface in a first position and a single phase interface in a second position.

2. A power component magazine as claimed in claim 1 wherein the connectors are moved up and down between the first and second positions.

3. A power component magazine as claimed in claim 2 wherein the connectors are secured to a panel that is movable up and down.

4. A power component magazine as claimed in claim 3 wherein the panel is the rear panel of the power component magazine.

5. A power component magazine as claimed in claim 4 wherein the plate and side walls of the magazine are provided with apertures to enable the plate to be secured to the side walls in either the first or second positions.

6. A power component magazine having a plurality of bays for receiving a plurality of components and a connector for each bay for providing electrical connection between a component and power lines associated with the magazine, wherein each connector includes a first AC terminal and every third first AC terminal is connected to a respective power line.

7. A power component magazine as claimed in claim 6 wherein each connector has a second AC terminal and every third connector of each second AC terminal is connected to a respective power line.

8. A power component magazine as claimed in claim 6 wherein each connector has an earth terminal connected to a common earth line.

9. A method of assembling a power component magazine comprising:
a. supplying a power component magazine as claimed in claim 6; and
b. connecting all power lines to a common single phase AC supply line.

10. A method of assembling a power component magazine comprising:
a. supplying a power component magazine as claimed in claim 6; and
b. connecting the power lines to three respective three phase AC supply lines.

11. A method of assembling a power component magazine comprising:
a. supplying a power component magazine as claimed in claim 6; and
b. connecting two of the power lines to two respective AC supply lines.

12. A method of assembling a power component magazine comprising:
a. supplying a power component magazine as claimed in claim 7;
b. connecting all power lines connected to first terminals to a first single phase AC supply line and connecting all power lines connected to second terminals to a second single phase AC supply line.

13. A method of assembling a power component magazine comprising:
a. supplying a power component magazine as claimed in claim 7;
b. connecting all power lines connected to first terminals to a first single phase AC supply line and connecting all power lines connected to second terminals to a second neutral supply line.

14. A method of assembling a power component magazine comprising:
a. supplying a power component magazine as claimed in claim 7; and
b. connecting the power lines to three respective three phase AC supply lines.

15. A method as claimed in claim 14 wherein the power lines connected to each first AC terminal of each connector are connected to a different three phase AC power supply line than the second AC terminal of each connector.

16. A method of assembling a power component magazine comprising:
a. supplying a power component magazine as claimed in claim 7; and
b. connecting the power lines of the first terminals of each connector to three respective three phase AC supply lines; and
c. connecting the power lines of the second terminals of each connector to a neutral supply line.

17. A power component assembly comprising:
a. a power component magazine having a plurality of bays, each of a constant form factor; and
b. a plurality of power component modules, at least one of different dimensions, adapted to be accommodated within the bays, wherein the dimensions of all power component modules are multiples of the bay form factor.

18. A power component assembly as claimed in claim 17 wherein the multiples are integer multiples.

19. A power component assembly as claimed in claim 18 wherein the multiples are multiples of 1.75 inches in component width.

20. A power component assembly as claimed in claim 17 wherein the magazine has 10 bays.

21. A family of power components having different power ratings and different form factors wherein the form factor of each power component fits within a multiple of a standard form factor and each power component has connectors allowing engagement to a standard complementary connector.

22. A family of power components as claimed in claim 21 including single phase and three phase power components wherein the terminals of each single phase power component have a first relationship with each single phase power component and the terminals of each three phase power component have a second relationship with each three phase power component, different to the first relationship.

23. A family of power components as claimed in claim 22 wherein the terminals have a different vertical relationship.

24. A family of power components as claimed in claim 22 wherein the terminals of each power component are provided on a PCB edge connector.

25. A method of assembling a power supply comprising a component magazine having a rear connector plate securable in a first or second position and a plurality of power components, the method comprising the steps of:
a. Securing the connector plate in the first or second position in dependence upon whether the power supply is to be a single or three phase power supply; and
b. Inserting the power components in bays of the component magazine.
